(19) United States
(12) Patent Application Publication
(10) Pub. No.: US 2025/0286698 A1
(43) Pub. Date: Sep. 11, 2025

(54) METHOD FOR DETERMINING A NOISE POWER IN A PHASE-LOCKED LOOP OF A TECHNICAL SYSTEM

(71) Applicant: Robert Bosch GmbH, Stuttgart (DE)

(72) Inventors: Michael Wickert, Dresden (DE); Bernd Schmidtke, Leonberg (DE); Reiner Schnitzer, Reutlingen (DE)

(21) Appl. No.: 19/062,404

(22) Filed: Feb. 25, 2025

(30) Foreign Application Priority Data
Mar. 5, 2024 (DE) 10 2024 202 009.5

(51) Int. Cl. H04L 7/033

(52) U.S. Cl. CPC H04L 7/033

(57) ABSTRACT

A method for determining a noise power in a phase-locked loop of a technical system. The method includes: providing at least one resonator in the phase-locked loop; configuring the at least one resonator with respect to a center frequency, a bandwidth, and/or an integration time, wherein the integration time is specific to a time period for which the noise power is determined; determining the noise power in the phase-locked loop by means of the at least one resonator based on a summation of an energy of a phase error of the phase-locked loop for the configured integration time. A computer program, a device, and a storage medium, are also described.

### FIELD

The present invention relates to a method for determining a noise power in a phase-locked loop of a technical system. The present invention furthermore relates to a computer program, a device, and a storage medium for this purpose.

### BACKGROUND INFORMATION

A phase-locked loop (PLL) is a control system which stabilizes an output frequency by synchronizing it with a reference frequency. This is achieved by continuously adjusting the phase of the oscillator so that it matches the phase of the reference signal. PLLs are widely used in communication technology, for example in frequency synthesis, modulation, and demodulation.

Noise is a major disturbance for PLL systems. It can cause phase jitter, which impairs the accuracy and stability of the PLL. For example, phase noise occurs when random variations in the phase of the oscillator are caused by thermal noise or other external disturbances. This leads to deterioration in the signal quality and can cause significant problems in critical applications such as high-speed data transmission. Managing and minimizing noise in PLL systems is therefore a central aspect in the design of such circuits.

For example, German Patent Application NO. DE 11 2018 007 419 T5 describes techniques for reducing or attenuating the phase noise of a digital phase-locked loop.

German Patent Application No. DE 10 2013 005 054 A1 describes a phase-locked loop for generating an output signal.

### SUMMARY

The present invention relates to a method, a computer program, a device, and a computer-readable storage medium. Further features and details of the present invention can be found in the disclosure herein. Features and details which are described in connection with the method according to the present invention of course also apply in connection with the computer program according to the present invention, the device according to the present invention, and the computer-readable storage medium according to the present invention, and respectively vice versa, so that, with respect to the disclosure, mutual reference is or can be made to the individual aspects of the present invention at all times.

The present invention relates in particular to a method for determining a noise power in a phase-locked loop of a technical system. According to an example embodiment of the present invention, the method includes the following steps, wherein the steps can be carried out repeatedly and/or successively:
providing at least one resonator in the phase-locked loop,
configuring the at least one resonator with respect to a center frequency, a bandwidth, and/or an integration time, wherein the integration time is specific to a time period for which the noise power is determined,
determining the noise power in the phase-locked loop by means of the at least one resonator on the basis of a summation of an energy of a phase error of the phase-locked loop for the configured integration time.

According to an example embodiment of the present invention, the phase-locked loop (PLL) is preferably a digital phase-locked loop. The phase error can be provided by a phase detector of the phase-locked loop. The technical system may, for example, be a radar system. The summation of the phase error may be performed, for example, by the phase detector determining the phase error at certain time intervals. The energy from this determined phase error can subsequently be added to a current total in each case. In terms of time, the addition or summation is preferably performed for a duration of the configured integration time. The method advantageously allows monitoring of the noise power in the resulting frequency range of the at least one resonator, wherein the resulting frequency range results from the configured center frequency and the configured bandwidth. This makes it possible to assess and monitor a quality of the phase-locked loop or of an oscillator of the phase-locked loop. Furthermore, the method can make it possible to monitor the phase noise in the phase-locked loop, in particular in a synthesizer of the phase-locked loop, on the basis of the determined noise power. This can be performed in an open-loop mode (oscillator only) and in a closed-loop mode. A technical system that comprises the phase-locked loop can thus advantageously check basic noise properties of the oscillator after power-up, before potentially sensitive measurements are performed. During the measurements, the method can advantageously be used to continuously monitor the phase noise with very little hardware.

According to a further advantageous example embodiment of the present invention, the method may further comprise the following step:
specifying a number of resonators to be provided.

This makes it possible to advantageously select, on the basis of the resonators provided, multiple frequency ranges that are relevant to a given application and for which the noise power can be determined. The center frequency, bandwidth, and integration time can be individually configured for each of the specified number of resonators to be provided.

Advantageously, the present invention can provide that the summation of the phase error is performed by a squaring circuit of the at least one resonator. A squaring circuit is in particular an electronic circuit which is used to generate the square of an input signal, whereby the output signal is accordingly proportional to the square of the input signal. Analog multipliers can be used for this purpose, which multiply the input signal by itself. A result of the summation after the squaring circuit can be divided by a number of samples used and then corresponds in particular to the noise power in the configured resonator bandwidth. As an alternative to squaring, it would also be possible to form the magnitude of the phase errors with subsequent summation as a simplified criterion for error handling by means of an appropriate magnitude formation circuit.

According to an example embodiment of the present invention, it is possible that the method further comprises the following steps:
defining at least one threshold value for the noise power,
comparing the determined noise power with the at least one threshold value,
performing at least one measure depending on a result of the comparison.

The threshold value can be defined individually for an application and may, for example, be based on empirical values. Furthermore, the threshold value can be specified by a safety requirement for the phase-locked loop or can result from the safety requirement. The result of the comparison indicates in particular whether the noise power exceeds the defined threshold value or not. By defining the at least one threshold value, it can advantageously be specified when an impairment of the phase-locked loop or of the technical system comprising the phase-locked loop is likely. Accordingly, such an impairment can be counteracted or appropriately responded to by means of the at least one measure. It is also possible that a restart, a repetition of a calibration process, or even an activation of an “emergency mode” (safe state) is triggered by such a threshold value exceedance.

Advantageously, within the scope of the present invention, it can be provided that the at least one measure is initiating an output of at least one warning message or of a current state of the noise power. The output may, for example, be carried out via an output unit such as a display and/or a loudspeaker and thus visually and/or acoustically.

Furthermore, according to an example embodiment of the present invention, the method may further comprise the following step:
scaling the phase error on the basis of a defined scaling factor in order to provide flexibility for determining the noise power.

As a result, the at least one resonator can advantageously be used for different phase amplitudes.

According to an example embodiment of the present invention, in a further possibility, the method may further comprise the following step:
varying the configured center frequency, bandwidth, and/or integration time, and/or a periodicity of determining the noise power in the phase-locked loop.

The variation can be performed with respect to a duration of a corresponding configuration of the at least one resonator with a certain periodicity. For example, a configuration could initially be changed every minute for a duration of five minutes, and a configuration could subsequently be changed every two minutes for a duration of ten minutes. It is also possible that the variation is initiated by a trigger condition, such as when the noise power exceeds a defined threshold value or remains below a defined threshold value for a defined duration.

The present invention also relates to a computer program, in particular a computer program product, comprising commands which, when the computer program is executed by a computer, cause the computer to carry out the method according to the present invention. The computer program according to the present invention thus delivers the same advantages as have been described in detail with reference to a method according to the present invention.

The present invention also relates to a device for processing data that is configured to carry out the method according to the present invention. For example, a computer which executes the computer program according to the present invention can be provided as the device. The computer can have at least one processor for executing the computer program. A non-volatile data memory can also be provided, in which the computer program is stored and from which the computer program can be read by the processor for execution.

The present invention can also relate to a computer-readable storage medium which comprises the computer program according to the present invention and/or commands which, when executed by a computer, cause the computer to carry out the method according to the present invention. The storage medium is formed, for example, as a data storage such as a hard drive and/or a non-volatile memory and/or a memory card. The storage medium can be integrated into the computer, for example.

Furthermore, the method according to the present invention can also be carried out as a computer-implemented method.

Further advantages, features, and details of the present invention can be found in the following description, in which exemplary embodiments of the present invention are described in detail with reference to the figures. The features herein can be essential to the present invention in each case, either individually or in any combination.

### BRIEF DESCRIPTION OF THE DRAWINGS

FIG. 1 is a schematic visualization of a method, a technical system, a device, a storage medium, and a computer program according to exemplary embodiments of the present invention.

FIG. 2 is a schematic representation of a phase-locked loop with a resonator according to exemplary embodiments of the present invention.

### DETAILED DESCRIPTION OF EXAMPLE EMBODIMENTS

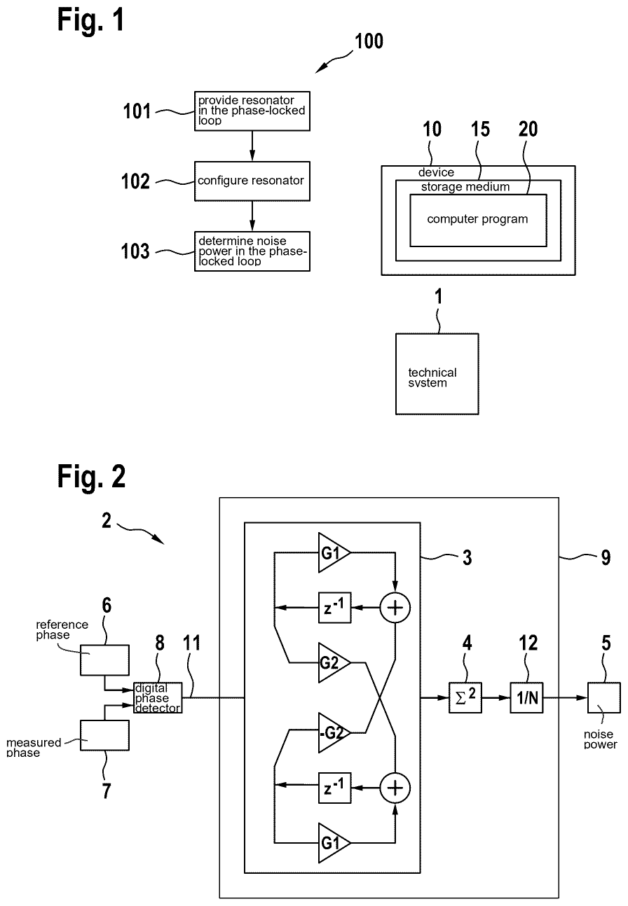

FIG. 1 schematically shows a method 100, a technical system 1, a device 10, a storage medium 15, and a computer program 20 according to exemplary embodiments of the present invention.

FIG. 1 in particular shows an exemplary embodiment of a method 100 for determining a noise power 5 in a phase-locked loop 2 of a technical system 1. In a first step 101, at least one resonator 3 is provided in the phase-locked loop 2. In a second step 102, the at least one resonator 3 is configured with respect to a center frequency, a bandwidth, and/or an integration time, wherein the integration time is specific to a time period for which the noise power 5 is determined. In a third step 103, the noise power 5 in the phase-locked loop 2 is determined by the at least one resonator 3 on the basis of a summation of an energy of a phase error 11 of the phase-locked loop 2 for the configured integration time.

The method according to exemplary embodiments makes it possible in particular to monitor the phase noise in a phase-locked loop 2, in particular of a synthesizer in the open-loop mode (oscillator only) and closed-loop mode. A technical system 1 comprising the phase-locked loop 2 can thus advantageously check the basic noise properties of the oscillator after power-up, before potentially sensitive measurements are performed. During the measurements, the method according to exemplary embodiments can be used to continuously monitor the phase noise with very little hardware.

In a digital PLL 2, the instantaneous phase error 11 is available in particular at the output of the digital phase detector 8 on the basis of a comparison of a reference phase 6 with a measured phase 7 (cf. FIG. 2). One or more digital resonators 3 with configurable spectral sensitivity can be used according to exemplary embodiments to monitor configurable ranges of the spectrum. This advantageously makes it possible to report an error when a problem, i.e., in particular, a noise power 5 which exceeds a defined threshold value, is detected.

FIG. 2 shows an exemplary embodiment of a phase-locked loop 2 with a resonator 3. The available measured phase error 11 is preferably fed to at least one or to a series of programmable resonators 3 in order to obtain their spectral power within a configurable frequency band. The theory for describing the center frequency and the bandwidth of such structures is conventional and can be described analytically. The structure shown of the resonator 3 preferably places two zeros in the complex z-plane within the unit circle, with the following relationships between the center frequency f_{ctr} and the quality factor Q. The two gain coefficients G₁ and G₂ preferably jointly determine the center frequency f_{ctr} and the quality Q of the resonator. Z⁻¹ in particular represents a delay of one clock cycle of the frequency f_{clk}.

$${ω}_{0} = 2 \times π \times {f}_{ctr} / {f}_{c l k}$$

$${G}_{1} = {e}^{- \frac{{ω}_{0}}{2 Q}} \cdot cos ( {ω}_{0} )$$

$$\vert {G}_{2} \vert = {e}^{- \frac{{ω}_{0}}{2 Q}} \cdot sin ( {ω}_{0} )$$

where f_{clk} describes the clock frequency of the input data.

Other higher-order resonator structures can also be used if the effective bandwidth is correctly taken into account. The filtered sample values after the resonator structure 3 are preferably squared and summed by means of a squaring circuit 4. This result is then divided by the number of samples used, in particular according to step 12 in FIG. 2, and corresponds to the noise power 5 in the given resonator bandwidth. The phase noise monitor 9 according to the exemplary embodiment in FIG. 2 thus comprises the resonator 3, the squaring circuit 4, and the division by the number of used samples N according to step 12.

Before a synthesizer of the phase-locked loop 2 is put into operation, the noise power 5 of the oscillator can thus advantageously be measured independently using the method according to exemplary embodiments. After closing the phase-locked loop 2, the phase noise monitor 9 according to FIG. 2, or the method for determining the noise power 5 according to exemplary embodiments of the present invention, can be used to compare the phase noise spectrum of the closed phase-locked loop 2 with an expected deviation from the behavior of the open phase-locked loop 2. During synthesizer operation, even during ongoing modulations, the phase noise monitor 9 or the method for determining the noise power 5 according to exemplary embodiments of the present invention can be used to monitor certain frequency ranges continuously or in a round-robin process.

The above description of the embodiments describes the present invention exclusively in the context of examples. Of course, individual features of the embodiments, provided they make technical sense, can be freely combined with one another without departing from the scope of the present invention.

1-10. (canceled)

11. A method for determining a noise power in a phase-locked loop of a technical system, comprising the following steps:
providing at least one resonator in the phase-locked loop;
configuring the at least one resonator with respect to a center frequency and/or a bandwidth and/or an integration time, wherein the integration time is specific to a time period for which the noise power is determined;
determining the noise power in the phase-locked loop using the at least one resonator based on a summation of an energy of a phase error of the phase-locked loop for the configured integration time.

12. The method according to claim 11, further comprising:
specifying a number of resonators to be provided.

13. The method according to claim 11, wherein the summation of the phase error is performed by a squaring circuit of the at least one resonator.

14. The method according to claim 11, further comprising the following steps:
defining at least one threshold value for the noise power;
comparing the determined noise power with the at least one threshold value; and
performing at least one measure depending on a result of the comparison.

15. The method according to claim 14, wherein the at least one measure is initiating an output of: (i) at least one warning message or (ii) a current state of the noise power.

16. The method according to claim 11, further comprising the following step:
scaling the phase error based on a defined scaling factor in order to provide flexibility for determining the noise power.

17. The method according to claim 11, further comprising the following step:
varying: (i) the configured center frequency and/or bandwidth and/or integration time, and/or (ii) a periodicity of determining the noise power in the phase-locked loop.

18. A device for processing data, configured to determine a noise power in a phase-locked loop of a technical system, the device configured to:
provide at least one resonator in the phase-locked loop;
configure the at least one resonator with respect to a center frequency and/or a bandwidth and/or an integration time, wherein the integration time is specific to a time period for which the noise power is determined;
determine the noise power in the phase-locked loop using the at least one resonator based on a summation of an energy of a phase error of the phase-locked loop for the configured integration time.

19. A non-transitory computer-readable storage medium on which are stored commands for determining a noise power in a phase-locked loop of a technical system, the commands, when executed by a computer, causing the computer to perform the following steps:
providing at least one resonator in the phase-locked loop;
configuring the at least one resonator with respect to a center frequency and/or a bandwidth and/or an integration time, wherein the integration time is specific to a time period for which the noise power is determined;
determining the noise power in the phase-locked loop using the at least one resonator based on a summation of an energy of a phase error of the phase-locked loop for the configured integration time.
